(19) United States
(12) Patent Application Publication
(10) Pub. No.: US 2025/0264911 A1
(43) Pub. Date: Aug. 21, 2025

(54) DISPLAY DEVICE

(71) Applicant: LG Display Co., Ltd., Seoul (KR)

(72) Inventor: Hakyeol KWON, Gumi-si (KR)

(73) Assignee: LG Display Co., Ltd., Seoul (KR)

(21) Appl. No.: 19/029,046

(22) Filed: Jan. 17, 2025

(30) Foreign Application Priority Data
Feb. 15, 2024 (KR) 10-2024-0021792

(51) Int. Cl. G06F 1/16; H10K 59/80; H10K 77/10; H10K 102/00

(52) U.S. Cl. CPC G06F 1/1652; H10K 59/8722; H10K 59/8793; H10K 77/111; H10K 2102/311

(57) ABSTRACT

A display device according to an aspect of the present disclosure, includes a plurality of plates having different thermal expansion coefficients, an adhesive layer disposed on the plurality of plates, and a display panel disposed on the adhesive layer. Each of the plurality of plates has a curved shape. Therefore, the display device may be a curved display device having various curvatures.

### CROSS-REFERENCE TO RELATED APPLICATIONS

This application claims priority to Korean Patent Application No. 10-2024-0021792, filed in the Republic of Korea on Feb. 15, 2024, the entire contents of which are hereby expressly incorporated by reference into the present application.

### BACKGROUND

### Field

The present disclosure relates to a display device, and more particularly, to a curved display device.

### Discussion of the Related Art

As the information society develops, the demand for display devices for displaying images is increasing in various forms. Accordingly, recently, various display devices, such as a liquid crystal display (LCD), a plasma display panel (PDP), an organic light emitting display (OLED), or a quantum dot light emitting display (QLED), are being utilized.

Display devices are expanding their scope of application from computer monitors and TVs to automobiles. As such, studies are being conducted to have a wide display area without reducing the visibility of images depending on the location of users.

Specifically, recently, in order to suppress degradation of visibility of an image according to the position of a user, studies on curved display devices with a predetermined curvature are being actively conducted.

### SUMMARY OF THE DISCLOSURE

An object to be achieved by the present disclosure is to provide a curved display device which is implemented in various shapes.

Another object to be achieved by the present disclosure is to provide a display device in which a failure, which can be generated during a process of bonding a plurality of plates and a display panel and implementing a curved shape, is minimized or prevented.

Still another object to be achieved by the present disclosure is to provide a display device which reduces manufacturing costs.

Another object to be achieved by the present disclosure is to provide a curved display device which addresses the limitations and disadvantages associated with the related art.

Objects of the present disclosure are not limited to the above-mentioned objects, and other objects, which are not mentioned above, can be clearly understood by those skilled in the art from the following descriptions.

According to an aspect of the present disclosure, a display device includes a plurality of plates which has different thermal expansion coefficients and has a curved shape; an adhesive layer disposed on the plurality of plates; and a display panel disposed on the adhesive layer. A flat plate and a flat display panel which have been used in the related art are used as it is to minimize defects which can be generated during the manufacturing process while saving the manufacturing cost.

Other detailed matters of the example embodiments are included in the detailed description and the drawings.

According to an aspect of the present disclosure, a display device includes a plurality of plates having different thermal expansion coefficients to have various curvatures or various shapes.

According to an aspect of the present disclosure, a curved shape is formed using a plurality of plates and a display panel which have flat shapes so that a configuration such as a curved plate, display panel, or cover member which is separately manufactured may not be necessary.

According to an aspect of the present disclosure, the manufacturing cost of a curved display device can be reduced.

According to an aspect of the present disclosure, when a curved shape is implemented, a failure during the process, such as bubbles or creases can be suppressed and delamination between layers can be suppressed.

The effects according to an aspect of the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a perspective view of a display device according to an example embodiment of the present disclosure;

FIG. 2 is a cross-sectional view of a display device according to an example embodiment of the present disclosure;

FIG. 3 is a schematic exploded perspective view of a plurality of plates, an adhesive layer, and a display panel of a display device according to an example embodiment of the present disclosure;

FIGS. 4A to 4C are process cross-sectional views for explaining a manufacturing process of a display device according to an example embodiment of the present disclosure;

FIG. 5 is a cross-sectional view of a display device according to another example embodiment of the present disclosure;

FIG. 6 is a schematic exploded perspective view of a plurality of plates, a sub adhesive layer, and a display panel of a display device according to another example embodiment of the present disclosure;

FIG. 7 is a cross-sectional view of a display device according to still another example embodiment of the present disclosure; and

FIG. 8 is a schematic exploded perspective view of a plurality of plates, a sub adhesive layer, and a display panel of a display device according to still another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed therebetween, or it can be directly on the another element or layer.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Same reference numerals generally denote same elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” fully encompasses all the meanings and coverages of the term “may.”

Hereinafter, a display device according to example embodiments of the present disclosure will be described in detail with reference to accompanying drawings. All the components of each display device according to all embodiments of the present disclosure are operatively coupled and configured.

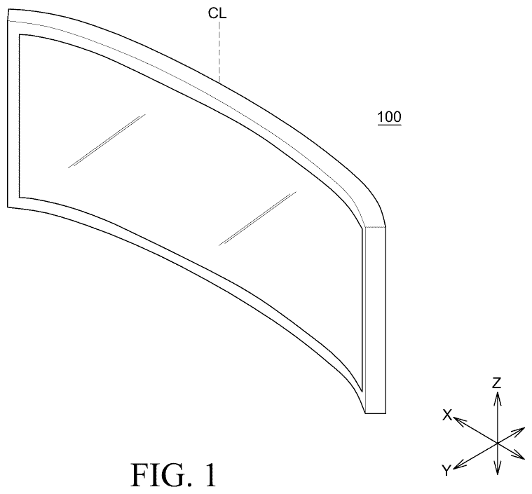

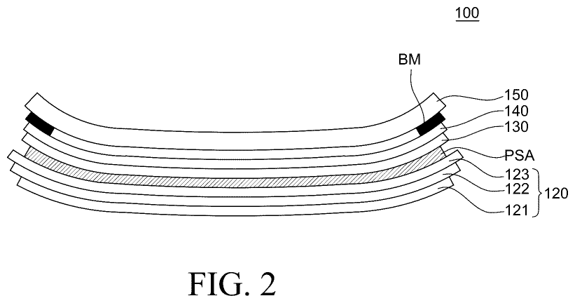

FIG. 1 is a schematic perspective view of a display device according to an example embodiment of the present disclosure and FIG. 2 is a schematic cross-sectional view of a display device according to an example embodiment of the present disclosure.

Referring to FIGS. 1 and 2, a display device 100 according to an example embodiment of the present disclosure includes a plurality of plates 120, an adhesive layer PSA, and a display panel 130.

Hereinafter, an X-axis can represent a long-side direction of the display device 100 and can be represented as a first direction. Further, a Y-axis can represent a bent direction of the display device 100 or a thickness direction of the display device 100 and can be represented as a second direction. A Z-axis can represent a short-side direction of the display device 100 and can be represented as a third direction.

Referring to FIG. 1, the display device 100 according to the example embodiment of the present disclosure can be curved to have a predetermined curvature. For example, a center portion where a center line CL of the display device 100 is located and both side portions of the display panel 130 of the display device 100 can have different curvatures.

As described above, the display device 100 according to the example embodiment of the present disclosure is a curved display device. At this time, the display device 100 has a concave center portion where the center line CL is located. Alternatively, the display device 100 has a convex center portion where the center line CL is located. In the present disclosure, the concave shape refers to a shape whose center is bent to be away from the direction of field of view. Further, in the present disclosure, the convex shape refers to a shape whose center is bent to be close to the direction of field of view.

Referring to FIG. 2, the display device 100 according to the example embodiment of the present disclosure includes a plurality of plates 120. The plurality of plates 120 is disposed below the display panel 130 to support the display panel 130 and protect the display panel 130 from the moisture, impacts, and heat from the outside. Further, the plurality of plates 120 is formed of a material having thermal conductivity to release heat generated in the display panel 130 to the outside.

In the drawings of the present disclosure, for the convenience of description, the plurality of plates 120 is configured by three plates including a first plate 121, a second plate 122, and a third plate 123, but the present disclosure is not limited thereto. For example, the plurality of plates 120 can include two plates or include four or more plates. At this time, each of the plurality of plates 120 can be bonded by means of an adhesive. The adhesive can be a pressure sensitive adhesive, but is not limited thereto. At this time, the adhesive used to bond the plurality of plates 120 can be disposed on the entire top surface or bottom surface of the plurality of plates 120.

Each of the plurality of plates 120 can have the same size and the same shape. At this time, the same size can mean that the lengths of the long-side and the short-side of the plate are the same and the areas on the plane are the same. The plurality of plates 120 can have the same thickness, but is not limited thereto. Each of the plurality of plates 120 can be laminated so as to completely overlap. For example, the plurality of plates 120 is sequentially laminated such that a top surface of the first plate 121 and a bottom surface of the second plate 122 completely overlap and a top surface of the second plate 122 and a bottom surface of the third plate 123 completely overlap. In the present disclosure, a top surface refers to a surface close to the direction of field of view and a bottom surface refers to a rear surface thereof.

The plurality of plates 120 can have shapes bent to have different curvatures. Further, the shape can be a curved shape corresponding to the shape of the display device 100. For example, when the center portion of the display device 100 is concave, the center portions of the plurality of plates 120 can also be concave. Further, when the center portion of the display device 100 is convex, the center portions of the plurality of plates 120 can also be convex. At this time, each of the plurality of plates 120 can have the same shape.

Each of the plurality of plates 120 includes plates having different thermal expansion coefficients. At this time, each of the plurality of plates 120 can be metal plates. For example, each of the plurality of plates 120 can be a metal plate including any one of aluminum, manganese, copper, nickel, iron, and molybdenum, but is not limited thereto. For example, each of the plurality of plates 120 can be different types of metal plates. At this time, the placement order of each of the plurality of plates 120 can vary depending on the shape of the display device 100.

When the center portion of the display device 100 has a concave portion, a plate disposed on a lowest end, among the plurality of plates 120, can have the largest thermal expansion coefficient. Further, when the center portion of the display device 100 has a concave portion, as the plurality of plates 120 is closer to the bottom, the thermal expansion coefficient can be increased. For example, when the first plate 121, the second plate 122, and the third plate 123 are sequentially laminated from the bottom and the center of the display device 100 has a concave portion, the first plate 121 can have the largest thermal expansion coefficient, the second plate 122 can have a larger thermal expansion coefficient, and the third plate can have the smallest thermal expansion coefficient.

Further, when the center portion of the display device has a convex shape, the thermal expansion coefficient of the plate disposed on the bottom of the plurality of plates can be the smallest. When the center portion of the display device has a convex shape, as the plurality of plates is closer to the bottom, the thermal expansion coefficient can be reduced. For example, the first plate, the second plate, and the third plate are sequentially laminated from the bottom and the center portion of the display device has a convex shape, the first plate can have the smallest thermal expansion coefficient, the second plate can have a smaller thermal expansion coefficient, and the third plate can have the largest thermal expansion coefficient.

In the plurality of plates 120, the thermal expansion coefficient of each plate can vary depending on the change in the shape of the display device 100. For example, in order to implement a curved degree required for the shape of the display device 100, a thermal expansion coefficient of each of the plurality of plates 120 can be selected.

Further, each of the plurality of plates 120 can be bonded to each other by means of a plate adhesive layer. At this time, the plate adhesive layer can be a pressure sensitive adhesive, but is not limited thereto. The plate adhesive layer can be disposed on a top surface or a bottom surface of each of the plurality of plates 120. Further, the plate adhesive layer can have the same size as a top surface or a bottom surface of each of the plurality of plates 120 and completely overlap the top surface or the bottom surface of each of the plurality of plates 120. For example, a first plate adhesive layer can be disposed on the top surface of the first plate 121 and a second plate 122 can be disposed on the first plate adhesive layer. In addition, a second plate adhesive layer can be disposed on a top surface of the second plate 122 and a third plate adhesive layer can be disposed on the second plate adhesive layer. At this time, the first plate adhesive layer and the second plate adhesive layer can be the same adhesive layer.

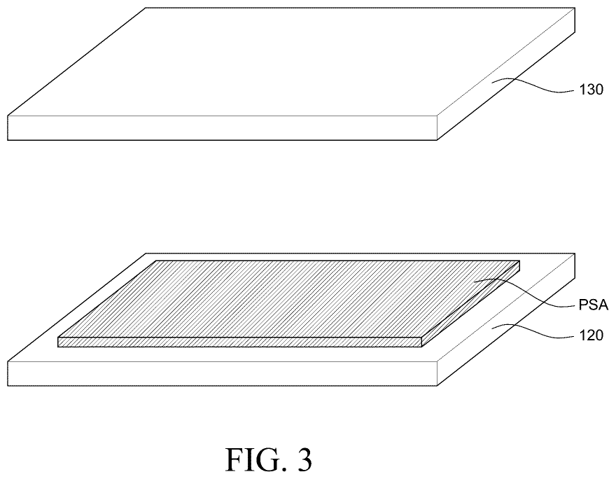

In the display device 100 according to the example embodiment of the present disclosure, the adhesive layer PSA is disposed on the plurality of plates 120. Hereinafter, the adhesive layer PSA will be described in detail with reference to FIGS. 2 and 3.

FIG. 3 is a schematic exploded perspective view of a plurality of plates, an adhesive layer, and a display panel of a display device according to an example embodiment of the present disclosure.

Referring to FIGS. 2 and 3, in the display device 100 according to the example embodiment of the present disclosure, an adhesive layer PSA is disposed between the plurality of plates 120 and the display panel 130. Therefore, the display panel 130 can be bonded onto the plurality of plates 120. Further, the adhesive layer PSA can protect the display panel 130 from moisture, oxygen, and shocks from the outside.

The size of the adhesive layer PSA can be smaller than the plurality of plates 120. For example, an area of the bottom surface of the adhesive layer PSA can be smaller than an area of the top surface of the plate at the top, among the plurality of plates 120. Therefore, an end of the adhesive layer PSA can be disposed inside more than the plurality of plates 120. Further, the end of the adhesive layer PSA may not be connected to the end of the plurality of plates 120. Therefore, the adhesive layer PSA may not be disposed at an edge of the top surface of the plurality of plates 120. For example, the end of the plurality of plates 120 can be spaced apart from the end of the adhesive layer PSA by at least a thickness of the adhesive layer PSA. At this time, the thickness of the adhesive layer PSA is not limited in the present disclosure.

A planar shape of the bottom surface of the adhesive layer PSA can be the same as a planar shape of a top surface of the plate located at the top of the plurality of plates 120. For example, when the planar shape of the top surface of the uppermost plate of the plurality of plates 120 is a rectangle, a planar shape of the bottom surface of the adhesive layer PSA can be rectangular, but is not limited thereto.

The center portion of the adhesive layer PSA can be concave or convex. A bottom surface of the adhesive layer PSA can correspond to a shape of the top surface of the plurality of plates 120 and when the top surface of the plurality of plates 120 is concave, the bottom surface of the adhesive layer PSA can also be concavely bent. Further, the top surface and the bottom surface of the adhesive layer PSA can have the same shape.

At this time, the adhesive layer PSA can be a pressure sensitive adhesive, but is not limited thereto.

The display panel 130 is disposed on the adhesive layer PSA.

The display panel 130 can include pixels defined by data lines and gate lines. Each of the pixels can include an organic light emitting diode (hereinafter, referred to as “OLED”) which is a self-emitting element. The OLED can include an anode electrode, a cathode electrode, and an organic compound layer interposed therebetween. The organic compound layer can include an emission layer (EML) and further include a common layer. The common layer can include at least any one or more selected from a group consisting of a hole injection layer (HIL), a hole transport layer (HTL), an electron transport layer (ETL), and an electron injection layer (EIL).

Each pixel can include a driving thin film transistor which controls a driving current flowing through OLED according to a gate-source voltage, a storage capacitor which constantly maintains the gate-source voltage of the driving thin film transistor for one frame, and at least one or more switching thin film transistors. The switching thin film transistors program the gate-source voltage of the driving thin film transistor in response to a gate pulse (or a scan pulse). The driving current is determined by the gate-source voltage of the driving thin film transistor according to a data voltage and a threshold voltage of the driving thin film transistor and a luminance of the pixel is proportional to a magnitude of the driving current flowing through the OLED.

The display panel 130 can be fixed onto the plurality of plates 120 by the adhesive layer PSA. Therefore, the shape of the display panel 130 can correspond to a shape of the adhesive layer PSA. For example, when a center portion of the top surface of the adhesive layer PSA is concave, a center portion of the bottom surface of the display panel 130 can also be correspondingly concavely bent. Further, when a center portion of the top surface of the adhesive layer PSA is convex, a center portion of the top surface of the display panel 130 can also be correspondingly convexly bent. The top surface and the bottom surface of the display panel 130 can have the same shape. The planar shape of the bottom surface of the display panel 130 can be the same as the planar shape of the top surface of the adhesive layer PSA. For example, when the planar shape of the bottom surface of the display panel 130 is a rectangle, a planar shape of the top surface of the adhesive layer PSA can also have the rectangular shape, but is not limited thereto.

The area of the bottom surface of the display panel 130 can be larger than an area of the top surface of the adhesive layer PSA. Therefore, an end of the display panel 130 can be disposed outside more than the end of the adhesive layer PSA. Therefore, the adhesive layer PSA may not be disposed at an edge of the bottom surface of the display panel 130. Further, the end of the display panel 130 can be spaced apart from the end of the adhesive layer PSA by at least a thickness of the adhesive layer PSA.

A polarization plate 140 can be disposed on or above the display panel 130. The polarization plate 140 can polarize light which is incident from the outside. Therefore, light which passes through the polarization plate 140 to be incident into the display device 100 can be reflected in the display device 100 so that a phase can be shifted. As described, phase-shifted light may not pass through the polarization plate 140 again. Therefore, light which is incident into the display device 100 from the outside of the display device 100 is not released to the outside of the display device 100 so that the external light reflection of the display device 100 can be reduced.

The polarization plate 140 can be configured by a polarizer and a protective film which protects the polarizer and can be configured by coating a polarization material for ensuring flexibility.

The polarization plate 140 can be the same size as the display panel 130. For example, an area of the bottom surface of the polarization plate 140 can be the same as an area of the top surface of the display panel 130. Further, the polarization plate 140 can be disposed on the display panel 130 to completely overlap the display panel 130.

The shape of the polarization plate 140 can correspond to a shape of the display panel 130. For example, when the center portion of the top surface of the display panel 130 is concave, a center portion of the bottom surface of the polarization plate 140 can correspondingly have a concave shape. Further, when the center portion of the top surface of the display panel 130 is convex, a center portion of the bottom surface of the polarization plate 140 can correspondingly have a convex shape. At this time, the top surface and the bottom surface of the polarization plate can have the same shape.

A black matrix BM can be disposed on the planarization plate 140. At this time, the black matrix BM can be disposed on the polarization plate 140 to enclose an edge of the polarization plate 140. Therefore, the black matrix BM can define a display panel 130 on which a screen is displayed. The black matrix BM can have the same width on all edges on the polarization plate 140 and if necessary, can have different widths on each edge.

The black matrix BM can be formed by printing carbon black composition using an inkjet method or a screen method and then curing the carbon black using ultraviolet ray, but is not limited thereto.

A cover member 150 can be disposed on the polarization plate 140 and the black matrix BM. The cover member 150 can protect the display panel 130 from the outside shock and suppress damages, such as scratch, and transmit light emitted from the display panel 130 to allow images on the display panel 130 to be seen to the outside.

The cover member 150 can have a quadrangular plate shape, but is not limited thereto. Further, the cover member 150 can be curved to have different curvatures. For example, the cover member 150 can have a concave center portion or a convex center portion. A shape of the cover member 150 can correspond to shapes of the polarization plate 140, the display panel 130, or the plurality of plates 120 disposed below the cover member 150.

The cover member 150 can be formed of glass, but is not limited thereto. When the cover member 150 is formed of glass, the cover member has rigidity so that the cover member 150 can more easily protect the display panel 130 from the shocks of the outside.

Further, an optical adhesive layer can be disposed between the display panel 130, the polarization plate 140, the black matrix BM, and the cover member 150. At this time, the optical adhesive layer can be optically clear adhesives (OCA), but is not limited thereto.

As the information society develops, the demand for display devices which display images is increasing in various forms. The display devices are expanding their scope of application from computer monitors and TVs to automobiles and demands on larger display area are increased. However, in the case of the display device having a flat surface, the larger the display area, the lower the visibility according to the position of the user. Therefore, in order to suppress degradation of visibility of an image according to the position of a user, studies on curved display devices with a predetermined curvature are being conducted.

Generally, in order to implement a curved display device, components, such as a plate, a display panel, a polarization plate, or a cover member which configures the display device need to be formed of a material with flexibility. As a result, most of the components which form the display device need to maintain a curved shape. To this end, the curved display device is implemented by a method of separately preparing a cover member which already has a curved shape and attaching the other components on the prepared cover member so as to correspond to a curved shape of the cover member.

However, according to this method, a manufacturing process for separately manufacturing a curved cover member is additionally necessary, which results in increased process time. Further, as a separate process is added, the manufacturing cost is also increased. Further, other components are bonded onto the cover member having an already-made shape so that it is difficult to change the shape of the display device to another shape.

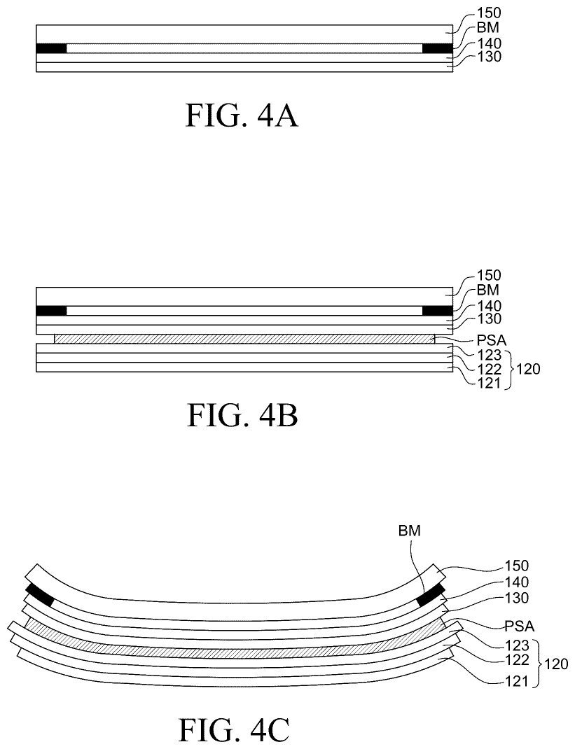

Therefore, the display device 100 according to the example embodiment of the present disclosure includes a plurality of plates 120 having different thermal expansion coefficients so that a curved cover member which is separately manufactured is not necessary, but a curved display device 100 can be implemented with a flat cover member. This will be described in more detail below with reference to FIGS. 4A to 4C.

FIGS. 4A to 4C are process cross-sectional views for explaining a manufacturing process of a display device according to an example embodiment of the present disclosure.

First, referring to FIG. 4A, in order to manufacture the display device 100 according to the example embodiment, first, a flat display panel 130, a polarization plate 140, a black matrix BM, and a cover member 150 are sequentially laminated. At this time, each layer can be bonded using an optically clear adhesive (OCA).

Next, referring to FIG. 4B, a plurality of plates 120 layer in which the first plate 121, the second plate 122, and the third plate 120 are sequentially laminated is manufactured. At this time, the first plate 121, the second plate 122, and the third plate 123 can be bonded using a pressure sensitive adhesive (PSA). Further, the first plate 121 can be formed of a metal having the largest thermal expansion coefficient, among the plurality of plates 120 and the third plate 123 can be formed of a metal having the smallest thermal expansion coefficient. The adhesive layer PSA having an area smaller than the top surface of the plurality of plates 120 is disposed on the plurality of plates 120 layer manufactured as described above. At this time, the adhesive layer PSA is disposed at the center of the top surface of the plurality of plates 120 layer, but is not disposed at the edge of the top surface of the plurality of plates 120 layer. A structure in which the display panel 130, the polarization plate 140, the black matrix BM, and the cover member 150 which are manufactured in advance are sequentially laminated is disposed on the adhesive layer PSA.

Next, referring to FIG. 4C, heat is applied to the laminated structure and thus the plurality of plates 120 having different thermal expansion coefficients expands at different ratios to implement a curved shape. For example, the first plate 121 configured by a metal plate having the highest thermal expansion coefficient expands the most by the heat and the third plate 123 configured by a metal plate having the lowest thermal expansion coefficient expands the least by the heat. Therefore, the first plate 121 located at the outermost side of the display device 100 expands the most, the second plate 122 disposed inside more than the first plate 121 expands the second most, and the third plate 123 which is disposed at the innermost side, among the plurality of plates 120, expands the least. Accordingly, the plurality of plates 120 naturally implements a curved shape with a concave center according to different expansion rates.

As described above, the display device 100 according to the example embodiment of the present disclosure includes a plurality of plates 120 having different thermal expansion coefficients. As described above, when heat is applied, each of the plurality of plates 120 having different thermal expansion coefficients expands with different expansion rates.

For example, in the structure in which the first plate 121, the second plate 122, and the third plate 123 are sequentially laminated, when the magnitude of the thermal expansion coefficient is the first plate 121>the second plate 122>the third plate 123, the first plate 121 disposed at the outermost side expands the most, the second plate 122 expands the second most, and the third plate 123 expands the least. As described above, the curved shape having a concave center is implemented by different expansion rates.

As another example, in the structure in which the first plate 121, the second plate 122, and the third plate 123 are sequentially laminated, when the magnitude of the thermal expansion coefficient is the first plate 121<the second plate 122<the third plate 123, conversely, the first plate 121 disposed at the outermost side expands the least and the third plate 123 disposed at the innermost side expands the most. Accordingly, the third pate disposed at the innermost side, among the plurality of plates, expands the most so that a curved shape with a convex center is implemented.

As described above, the display device 100 according to the example embodiment of the present disclosure includes a plurality of plates 120 having different thermal expansion coefficients to implement a curved display device 100 having various shapes. Further, the thermal expansion coefficient of each of the plurality of plates 120 and a temperature of heat to be applied are adjusted to adjust the curvature of the display device 100 in various ways.

Together with this, in the display device 100 according to the example embodiment of the present disclosure, each component including the cover member 150 is laminated in a flat state to omit a process of separately forming the curved cover member and other components and use flat components which have been used in the related art as it is. Therefore, the manufacturing process time can be shortened, and the cost can be saved.

In the meantime, when a curved cover member is separately prepared and then other flat components are bonded to the cover member, the flat components need to be physically curved to be bonded to the cover member. In this case, in other components which are attached to the cover member to be physically deformed, a repulsive force is generated to return to its original shape. Specifically, a larger repulsive force is generated at the outer part of the component having a larger strain and thus a residual stress is generated. As described above, when the repulsive force is generated in the other components bonded to the curved cover member, the adhesive force between the components and the cover member can be degraded so that bubbles and creases can be created. In the worst case, each component can be peeled.

Therefore, in the display device 100 according to the example embodiment of the present disclosure, after bonding all configuration layers including the cover member 150 in a flat state, the curved shape is implemented. Further, a plurality of plates 120 having different thermal expansion coefficients is included to bend all the components together. As described above, components with different shapes are not bonded so that the repulsive force generated between the components can be suppressed. Therefore, the bubbles and creases generated by the repulsive force between the components can be suppressed and the separation of the components can be suppressed.

However, even though all the components are bonded in the flat shape, the components can be physically deformed to have a curved shape so that a minimum repulsive force can be generated between the components. The repulsive force can be mainly generated at the outer area of each component which can be relatively significantly deformed.

Accordingly, in the display device 100 according to the example embodiment of the present disclosure, an adhesive layer PSA having a smaller area than the plurality of plates 120 and the display panel 130 is disposed between the plurality of plates 120 and the display panel 130. As described above, the adhesive layer PSA is not disposed at the edge area of the top surface of the plurality of plates 120 and the edge area of the bottom surface of the display panel 130 to minimize the repulsive force generated at the outside area.

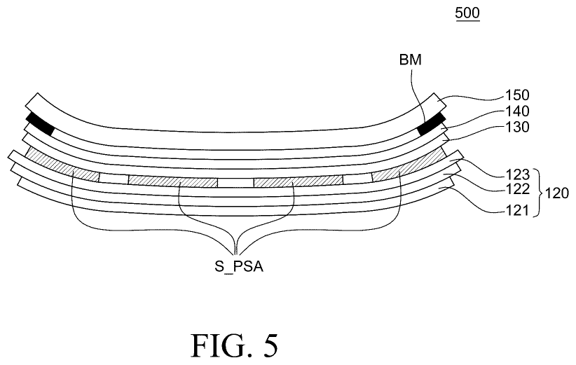

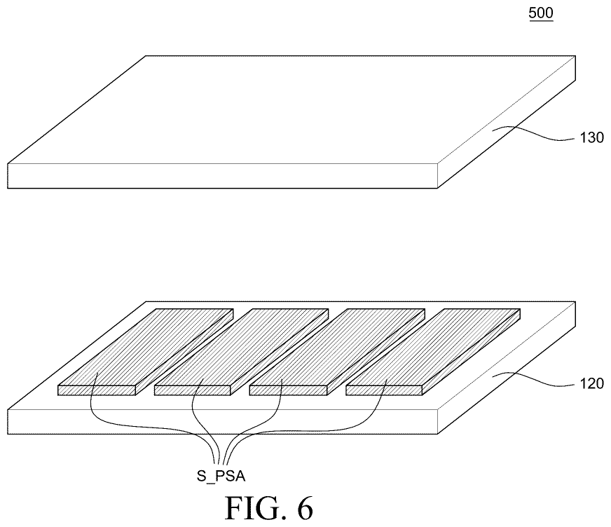

FIG. 5 is a cross-sectional view of a display device according to another example embodiment of the present disclosure and FIG. 6 is a schematic exploded perspective view of a plurality of plates, a sub adhesive layer, and a display panel of a display device according to another example embodiment of the present disclosure. A main difference between a display device 500 of FIGS. 5 and 6 and the display device 100 of FIGS. 1 to 3 is a sub adhesive layer S_PSA, but the other configurations are substantially the same, so that a redundant description will be omitted or may be briefly provided.

Referring to FIGS. 5 and 6, the display device 500 according to another example embodiment of the present disclosure can include a plurality of sub adhesive layers S_PSA which is spaced apart from each other between the plurality of plates 120 and the display panel 130. At this time, the plurality of sub adhesive layers S_PSA can have the same size. Here, the size is a concept including a horizontal length, a vertical length, and a thickness of each of the plurality of sub adhesive layers S_PSA on the plan view. The plurality of sub adhesive layers S_PSA can be disposed inside more than all ends of the plurality of plates 120 and the display panel 130. For example, the plurality of sub adhesive layers S_PSA can be disposed to be spaced apart inwardly from four ends of the plurality of plates 120 and the display panel 130. Further, the plurality of sub adhesive layers S_PSA can be spaced apart from each other with the same interval. The distance between the plurality of sub adhesive layers S_PSA is smaller than a width of each of the plurality of sub adhesive layers S_PSA.

Even though in FIGS. 5 and 6, for the convenience of description, four sub adhesive layers S_PSA are illustrated, it is not limited thereto and other variations are possible and part of the present disclosure. For example, the sub adhesive layers S_PSA can be two or more.

Further, in FIGS. 5 and 6, for the convenience of description, one ends of the sub adhesive layers S_PSA are disposed on the same line. However, the present disclosure is not limited thereto. One ends of the sub adhesive layers S_PSA can be disposed on different lines.

The sub adhesive layer S_PSA can be a pressure sensitive adhesive, but is not limited thereto.

As described above, the display device 500 according to another example embodiment of the present disclosure includes a plurality of plates 120 having different thermal expansion coefficients to implement a curved display device 500 having various curvatures. Further, each configuration layer including the cover member 150 is laminated in a flat state to use the flat configuration layers of the related art as it is. Therefore, the manufacturing process time can be shortened, and the manufacturing cost can be saved or reduced.

Together with this, when the curved shape is implemented, a repulsive force which can be generated in each configuration layer can be suppressed or minimized. By doing this, defects, such as bubbles or creases, which can be generated in each configuration layer, can be suppressed, reduced or prevented, and the separation of each configuration layer can be suppressed or prevented.

Further, in the display device 500 according to another example embodiment of the present disclosure, the plurality of plates 120 and the display panel 130 can be bonded by means of the plurality of sub adhesive layers S_PSA. By doing this, the repulsive force which can be generated between the plurality of plates 120 and the display panel 130 can be reduced. Specifically, the sub adhesive layers S_PSA are spaced apart from each other so that the repulsive force which is generated not only in the outer part of the plurality of plates 120 and the display panel 130, but also in the entire area can be minimized.

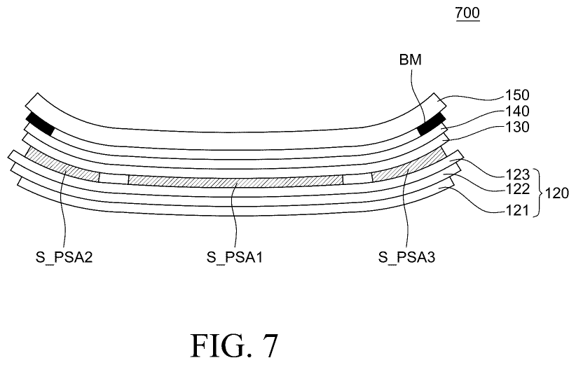

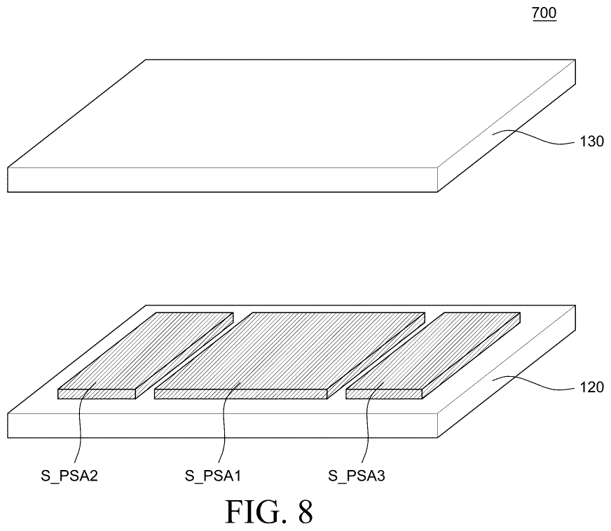

FIG. 7 is a cross-sectional view of a display device according to still another example embodiment of the present disclosure and FIG. 8 is a schematic exploded perspective view of a plurality of plates, a sub adhesive layer, and a display panel of a display device according to still another example embodiment of the present disclosure. A main difference between a display device 700 of FIGS. 7 and 8 and the display device 100 of FIGS. 1 to 3 is a configuration of a plurality of sub adhesive layers S_PSA1, S_PSA2, S_PSA3, but the other configurations are substantially the same, so that a redundant description will be omitted or may be briefly provided.

Referring to FIGS. 7 and 8, a plurality of sub adhesive layers S_PSA1, S_PSA2, S_PSA3 of a display device 700 according to still another example embodiment of the present disclosure can include a first sub adhesive layer S_PSA1, a second sub adhesive layer S_PSA2 disposed at one side of the first sub adhesive layer S_PSA1, and a third sub adhesive layer S_PSA3 disposed at the other side of the first sub adhesive layer S_PSA1. Further, the second sub adhesive layer S_PSA2 can be larger than the first sub adhesive layer S_PSA1 and the third sub adhesive layer S_PSA3. The first sub adhesive layer S_PSA1 and the third sub adhesive layer S_PSA3 can have the same size, but are not limited thereto.

The first sub adhesive layer S_PSA1, the second sub adhesive layer S_PSA2, and the third sub adhesive layer S_PSA3 can be disposed to be spaced apart from each other. At this time, a distance between the first sub adhesive layer S_PSA1 and the second sub adhesive layer S_PSA2 and a distance between the first sub adhesive layer S_PSA1 and the third sub adhesive layer S_PSA3 can be the same, but is not limited thereto.

All the first sub adhesive layer S_PSA1, the second sub adhesive layer S_PSA2, and the third sub adhesive layer S_PSA3 can be disposed inside more than all ends of the plurality of plates 120 and the display panel 130. For example, all the first sub adhesive layer S_PSA1, the second sub adhesive layer S_PSA2, and the third sub adhesive layer S_PSA3 can be disposed to be spaced apart from four ends of the plurality of plates 120 and the display panel 130.

Further, for the convenience of description, one ends of the first sub adhesive layer S_PSA1, the second sub adhesive layer S_PSA2, and the third sub adhesive layer S_PSA3 are disposed on the same line; however, it is not limited thereto. For example, one ends of the first sub adhesive layer S_PSA1, the second sub adhesive layer S_PSA2, and the third sub adhesive layer S_PSA3 can be disposed on different lines.

As described above, the display device 700 according to still another example embodiment of the present disclosure can implement a curved display device having various shapes. Further, a process of separately manufacturing components including the cover member 150 in a curved shape can be omitted. Therefore, the manufacturing process time can be shortened, and the manufacturing cost can be saved or reduced.

Together with this, when the curved shape is implemented, the repulsive force generated in each configuration layer can be minimized or reduced. Therefore, defects, such as bubbles or creases which can be generated by the repulsive force generated between the layers, can be minimized or prevented. Further, the separation of the configuration layers can be suppressed or prevented.

Further, the display device 700 according to still another example embodiment of the present disclosure can include a plurality of sub adhesive layers S_PSA1, S_PSA2, S_PSA3 which is spaced apart from each other between the display panel 130 and the plurality of plates 120. At this time, the first sub adhesive layer S_PSA1 disposed at the center or middle part can be larger in size than each of the second sub adhesive layer S_PSA2, and the third sub adhesive layer S_PSA3 disposed on both sides of the first sub adhesive layer S_PSA1. By doing this, the largest first sub adhesive layer S_PSA1 is disposed at the center or middle part where the repulsive force is relatively small to improve the adhesive force between the plurality of plates 120 and the display panel 130. Further, the second sub adhesive layer S_PSA2 and the third sub adhesive layer S_PSA3 which are smaller in size than the first sub adhesive layer S_PSA1 disposed at the center or middle part are disposed on both side portions where the repulsive force is relatively large to minimize the repulsive force. Accordingly, the repulsive force which can be generated between the plurality of plates 120 and the display panel 130 can be minimized while improving the adhesive force between the plurality of plates 120 and the display panel 130.

The example embodiments of the present disclosure can also be described as follows:

According to an aspect of the present disclosure, there is provided a display device. The display device comprises a plurality of plates having different thermal expansion coefficients and a curved shape, an adhesive layer disposed on the plurality of plates, and a display panel disposed on the adhesive layer.

According to aspects of the present disclosure, a center portion of the display device can have a concave shape. A plate disposed at the bottom, among the plurality of plates, can have the largest thermal expansion coefficient.

According to aspects of the present disclosure, a center portion of the display device can have a convex shape. A plate disposed at the bottom, among the plurality of plates, can have the smallest thermal expansion coefficient.

According to aspects of the present disclosure, the plurality of plates can be metal plates.

According to aspects of the present disclosure, an end of the adhesive layer can be disposed inside more than ends of the plurality of plates.

According to aspects of the present disclosure, an area of a top surface of the plate disposed at the top, among the plurality of plates, can be larger than an area of a bottom surface of the adhesive layer.

According to aspects of the present disclosure, ends of the plurality of plates and an end of the display panel can be spaced apart from an end of the adhesive layer by at least a thickness of the adhesive layer.

According to aspects of the present disclosure, the adhesive layer can include a plurality of sub adhesive layers which can be spaced apart from each other.

According to aspects of the present disclosure, the sub adhesive layers can have the same size.

According to aspects of the present disclosure, the plurality of sub adhesive layers can include a first sub adhesive layer, a second sub adhesive layer disposed at one side of the first sub adhesive layer, and a third sub adhesive layer disposed at the other side of the first sub adhesive layer, and the first sub adhesive layer can be larger than the second sub adhesive layer and the third sub adhesive layer.

According to aspects of the present disclosure, the display device can further comprise a polarization plate disposed on the display panel, and a cover member disposed on the polarization plate.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a plurality of plates having different thermal expansion coefficients, each of the plurality of plates having a curved shape;
an adhesive layer disposed on the plurality of plates; and
a display panel disposed on the adhesive layer.

2. The display device according to claim 1, wherein a center portion of the display device has a concave shape.

3. The display device according to claim 2, wherein a plate disposed at the bottom, among the plurality of plates, has the largest thermal expansion coefficient among the different thermal expansion coefficients of the plurality of plates.

4. The display device according to claim 1, wherein a center portion of the display device has a convex shape.

5. The display device according to claim 4, wherein a plate disposed at the bottom, among the plurality of plates, has the smallest thermal expansion coefficient among the different thermal expansion coefficients of the plurality of plates.

6. The display device according to claim 1, wherein the plurality of plates are metal plates.

7. The display device according to claim 1, wherein an end of the adhesive layer is disposed inside more than ends of the plurality of plates.

8. The display device according to claim 1, wherein an area of a top surface of the plate disposed at the top, among the plurality of plates, is larger than an area of a bottom surface of the adhesive layer.

9. The display device according to claim 1, wherein ends of the plurality of plates and an end of the display panel are spaced apart from an end of the adhesive layer by at least a thickness of the adhesive layer.

10. The display device according to claim 1, wherein the adhesive layer includes a plurality of sub adhesive layers that are spaced apart from each other.

11. The display device according to claim 10, wherein the plurality of sub adhesive layers have a same size.

12. The display device according to claim 10, wherein the plurality of sub adhesive layers include:
a first sub adhesive layer;
a second sub adhesive layer disposed at one side of the first sub adhesive layer; and
a third sub adhesive layer disposed at another side of the first sub adhesive layer, and
wherein the first sub adhesive layer is larger in size than at least one of the second sub adhesive layer and the third sub adhesive layer.

13. The display device according to claim 1, further comprising:
a polarization plate disposed on the display panel; and
a cover member disposed on the polarization plate.

14. The display device according to claim 1, wherein each of the plurality of plates is bonded to another of the plurality of plates by a plate adhesive layer.

15. The display device according to claim 14, wherein the plate adhesive layer is a pressure sensitive adhesive.

16. The display device according to claim 1, wherein a planar shape of a bottom surface of the adhesive layer is the same as a planar shape of a top surface of the plate located at a top of the plurality of plates.

17. The display device according to claim 1, wherein a center portion of the adhesive layer has a concave shape or a convex shape.

18. The display device according to claim 13, wherein a shape of the polarization plate corresponds to a shape of the display panel.

19. The display device according to claim 13, wherein a shape of the cover member corresponds to a shape of the polarization plate, a shape of the display panel, or a shape of the plurality of plates disposed below the cover member.

20. The display device according to claim 10, wherein a distance between the plurality of sub adhesive layers is smaller than a width of each of the plurality of sub adhesive layers.

21. The display device according to claim 1, wherein the adhesive layer is not disposed at an edge area of a top surface of the plurality of plates and an edge area of a bottom surface of the display panel.
